(19) United States
(12) Patent Application Publication
(10) Pub. No.: US 2011/0013057 A1
(43) Pub. Date: Jan. 20, 2011

(54) Output circuit for CCD solid-state imaging device, CCD solid-state imaging device, and imaging apparatus

(75) Inventor: Hiroki Hagiwara, Tokyo (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/801,320

(22) Filed: Jun. 3, 2010

(30) Foreign Application Priority Data
Jul. 15, 2009 (JP) 2009-167203

(51) Int. Cl. H04N 3/14; H03K 3/00

(52) U.S. Cl. 348/294; 327/109; 348/E03.016

(57) ABSTRACT

An output circuit for a CCD solid-state imaging device, includes: a first source follower circuit that is supplied with an imaging signal acquired by a floating diffusion, and includes a driver MOS transistor and a load MOS transistor; and a last source follower circuit that is supplied with an imaging signal amplified by the first source follower circuit, and includes a driver MOS transistor and a load MOS transistor each being a P-channel MOS transistor to provide an output signal.

### BACKGROUND OF THE INVENTION

1. Field of the Invention

The present invention relates to an output circuit for a CCD solid-state imaging device, a CCD solid-state imaging device equipped with the output circuit, and an imaging apparatus equipped with the CCD solid-state imaging device.

2. Description of the Related Art

CCD (Charge Coupled Device) type solid-state imaging devices are popular as a solid-state imaging apparatus. The CCD solid-state imaging device sequentially transfers charges, photoelectrically converted by photodiodes constituting individual pixels, to an output section by means of a vertical transfer CCD and a horizontal transfer CCD. The CCD solid-state imaging device acquires the charges as a voltage signal through a floating diffusion provided in the output section. The floating diffusion includes, for example, a PN junction diode. The voltage signal acquired by the diode is amplified by an output circuit connected to the diode, and output outside.

FIG. 14 is a diagram showing an example of the general circuit configuration of an output circuit connected to a floating diffusion. In the example in FIG. 14, the output circuit is configured to have two source follower circuits using N-channel MOS transistors.

A floating diffusion FD1 is connected to the gate of a driver MOS transistor DM1 to supply an input voltage Vin1 acquired by the floating diffusion FD1 to the driver MOS transistor DM1. A supply voltage VDD is supplied to the drain of the driver MOS transistor DM1. The source of the driver MOS transistor DM1 is connected to the drain of a load MOS transistor LM1 whose source is grounded via a resistor R1. A gate input voltage VG1 is supplied to the gate of the load MOS transistor LM1.

A voltage Vout1′, which is acquired at the node between the source of the driver MOS transistor DM1 and the drain of the load MOS transistor LM1, is supplied to the gate of a driver MOS transistor DM2 in the next stage. The supply voltage VDD is supplied to the drain of the driver MOS transistor DM2. The source of the driver MOS transistor DM2 is connected to the drain of a load MOS transistor LM2 whose source is grounded via the resistor R1. The gate input voltage VG1 is supplied to the gate of the load MOS transistor LM2.

Then, an output voltage Vout1 is acquired from the node between the source of the driver MOS transistor DM2 and the drain of the load MOS transistor LM2.

The output circuit for a CCD solid-state imaging device is configured in the above manner as two source follower circuits using N-channel MOS transistors.

FIG. 15 is a diagram showing a configuration example of an output circuit for a CCD solid-state imaging device, which is configured to have two source follower circuits using P-channel MOS transistors.

The configuration will be described referring to FIG. 15. A floating diffusion FD2 which is formed by a PN junction diode is connected to the gate of an N-channel driver MOS transistor DM3. This connection allows an input voltage Vin2 acquired by the floating diffusion FD2 to be supplied to the driver MOS transistor DM3. The driver MOS transistor DM3 has a source connected to the drain of a load MOS transistor LM3, and a drain grounded. A supply voltage VDD is supplied to the source of the load MOS transistor LM3 via a resistor R2. A gate input voltage VG2 is supplied to the gate of the load MOS transistor LM3.

A voltage Vout2′, which is acquired at the node between the source of the driver MOS transistor DM3 and the drain of the load MOS transistor LM3, is supplied to the gate of a driver MOS transistor DM4 in the next stage. The driver MOS transistor DM4 has a drain grounded, and a source connected to the drain of a load MOS transistor LM4. The supply voltage VDD is supplied to the source of the load MOS transistor LM4 via the resistor R2. The gate input voltage VG2 is supplied to the gate of the load MOS transistor LM4.

Then, an output voltage Vout2 is acquired from the node between the source of the driver MOS transistor DM4 and the drain of the load MOS transistor LM4.

The output circuit for a CCD solid-state imaging device is configured in the above manner as two source follower circuits using P-channel MOS transistors.

FIG. 16 shows a variation in the potential of the signals output via the output circuit in FIG. 14 or FIG. 15. Referring to FIG. 16, within a period of reading a signal from one pixel, the potential of the signal becomes a reference potential a, and then falls to a signal potential b. The signal potential b becomes a potential corresponds to the amount of charges stored in the pixel. Therefore, the amount of charges photoelectrically converted in each pixel can be detected by detecting a differential voltage c between the reference potential a and the signal potential b.

JP-A-11-234567 (Patent Document 1) describes an output circuit for a CCD solid-state imaging device in which a plurality of source follower circuits each having N-channel MOS transistors are connected. Patent Document 1 describes the configuration where a push-pull circuit having an N-channel MOS transistor and a P-channel MOS transistor is connected to a source follower circuit having N-channel MOS transistors.

JP-A-61-98255 (Patent Document 2) describes an output circuit for a source follower circuit having P-channel MOS transistors.

### SUMMARY OF THE INVENTION

The source follower circuit having N-channel MOS transistors as shown in FIG. 14 has a faster rise slew rate than a fall slew rate in principle, so that a larger circuit current needs to flow in order to increase the fall slew rate. The slow fall slew rate means that the time for the potential to fall from the reference potential a to the signal potential b is slow as in the case of FIG. 16.

Recently, there is a demand for increasing the fall slew rate to cope with multi-pixelation or an increase in frame rate. If the fall slew rate is not sufficient, the signal potential b cannot fall down to the value that corresponds to the amount of charges of pixels within the period of reading one pixel, resulting in improper signal reading of the imaging device. To make the fall slew rate of the output circuit higher, a large circuit current needs to flow as mentioned above. However, increasing the circuit current increases power consumption accordingly, which is contradictory to reduction in power consumption needed by the imaging apparatus.

The configuration described in the Patent Document 1 has a push-pull circuit connected to a source follower circuit to ensure a higher fall slew rate without increasing the circuit current.

In case of the push-pull circuit configuration, however, a signal needs to be input to the two gates of the N-channel MOS transistor and the P-channel MOS transistor, increasing the load capacitance as viewed from the previous stage to the push-pull circuit, so that an excess circuit current is needed at the previous stage. Consequently, the consumption current increases. Unlike the source follower configuration, the push-pull circuit configuration has a large variation in current value caused by a variation in the threshold voltage, Vth, of each MOS transistor. This undesirably increases a variation in frequency characteristic/power consumption of the imaging device.

A solution to such a problem is the use of a source follower circuit which uses P-channel MOS transistors of the opposite conductivity type to that of the transfer channel as described in Patent Document 2. An output circuit configured by a source follower circuit using P-channel MOS transistors has an excellent fall characteristic while reducing the power consumption. In addition, since a P-channel MOS transistor has smaller 1/f noise than an N-channel MOS transistor, noise in the output circuit can be reduced.

When the source follower circuit using N-channel MOS transistors as shown in FIG. 14 is replaced with the source follower circuit using P-channel MOS transistors as shown in FIG. 15, the following two problems arise.

The first problem is the increase of hot carriers. The voltage of the floating diffusion is restricted by the transfer from the horizontal transfer register, and is generally apt to become a high voltage (about 10 V). When a source follower having P-channel MOS transistors is connected simply as shown in FIG. 15, the drain terminal is grounded, so that the gate-drain potential difference and the source-drain potential difference become larger, generating a significant amount of hot carriers. The hot carriers lead to undesirable phenomena, such as reflection onto the sensor section, greater noise and lower reliability.

The second problem is a rise in supply voltage. The configuration described in Patent Document 2 uses enhanced P-channel MOS transistor in an N-channel region, making the source voltage higher than the gate voltage. That is, the relation between the input and output shown in FIG. 15 is Vin2<Vout2′<Vout2. To secure the dynamic range, the load MOS transistors LM3 and LM4 need to be driven in the saturation area, which requires that the supply voltage VDD should be set somewhat higher with respect to Vout2′ and Vout 2. For example, with Vin2=10 V, Vout2′=11 V and Vout2=12 V, VDD needs to be about 15 V or higher.

In case of the N-channel MOS source follower circuit shown in FIG. 14, the restrictions on the power source for securing the dynamic range are that the driver MOS transistors DM1 and DM2 need to operate in the saturation area (VDS>VGS−VTH), and in case of the enhanced (VTH>0 V) MOS transistors, VDD>Vin 1 needs to be fulfilled. With Vin=10 V, Vout1′=9 V and Vout1=8 V, for example, VDD needs to be about 10 V or higher. Therefore, the P-channel MOS transistor source follower circuit using enhanced P-channel MOS transistors as driver MOS transistors inevitably needs to increase the input voltage, which lessens the effect of reducing power consumption.

In consideration of the above-identified problems, it is desirable to provide an output circuit for a CCD solid-state imaging device, which copes with fast reading with low power consumption, an imaging device having the output circuit, and an imaging apparatus having the imaging device.

An output circuit for a CCD solid-state imaging device according to an embodiment of the invention is configured to include a first source follower circuit that is supplied with an imaging signal acquired by a floating diffusion, and a last source follower circuit that is supplied with an imaging signal amplified by the first source follower circuit.

The first source follower circuit has a driver MOS transistor and a load MOS transistor.

The last source follower circuit has a driver MOS transistor and a load MOS transistor each being a P-channel MOS transistor to provide an output signal.

This configuration that uses a source follower circuit having P-channel MOS transistors as the last source follower circuit can improve the fall characteristic of an output signal.

The embodiment of the invention brings about an effect of improving the fall characteristic of an output signal using the last source follower circuit having P-channel MOS transistors, while suppressing hot carriers and reducing the supply voltage.

Further, the use of a source follower circuit having P-channel MOS transistors as, for example, the first source follower circuit brings about an effect of suppressing noise to output a high-quality imaging signal.

### BRIEF DESCRIPTION OF THE DRAWINGS

FIG. 1 is a circuit diagram showing a configurational example (example 1) of an output circuit according to a first embodiment of the invention;

FIG. 2 is a block diagram showing a configurational example of an imaging apparatus according to the first embodiment of the invention;

FIG. 3 is a cross-sectional view showing an example of the structure of a substrate according to the first embodiment of the invention;

FIG. 4A is a potential chart of a general P-channel MOS transistor according to the related art, and FIGS. 4B and 4C are potential charts of a P-channel MOS transistor according to an embodiment of the invention;

FIG. 5 is a circuit diagram showing a configurational example (example 2) of the output circuit according to the first embodiment of the invention;

FIG. 6 is a circuit diagram showing a configurational example (example 3) of the output circuit according to the first embodiment of the invention;

FIG. 7 is a circuit diagram showing a configurational example (example 4) of the output circuit according to the first embodiment of the invention;

FIG. 8 is a circuit diagram showing a configurational example (example 5) of the output circuit according to the first embodiment of the invention;

FIG. 9 is a circuit diagram showing a configurational example (example 6) of the output circuit according to the first embodiment of the invention;

FIG. 10 is a circuit diagram showing a configurational example (example 7) of the output circuit according to the first embodiment of the invention;

FIG. 11 is a circuit diagram showing a configurational example (example 8) of the output circuit according to the first embodiment of the invention;

FIG. 12 is a circuit diagram showing a configurational example of an output circuit according to a second embodiment of the invention;

FIG. 13 is a circuit diagram showing a configurational example of an output circuit according to a third embodiment of the invention;

FIG. 14 is a circuit diagram showing a configurational example of an output circuit formed by an NMOS source follower circuit according to the related art;

FIG. 15 is a circuit diagram showing a configurational example of an output circuit formed by a PMOS source follower circuit according to the related art; and

FIG. 16 is a characteristic diagram showing a general variation in the output potential of a CCD imaging device.

### DESCRIPTION OF THE PREFERRED EMBODIMENTS

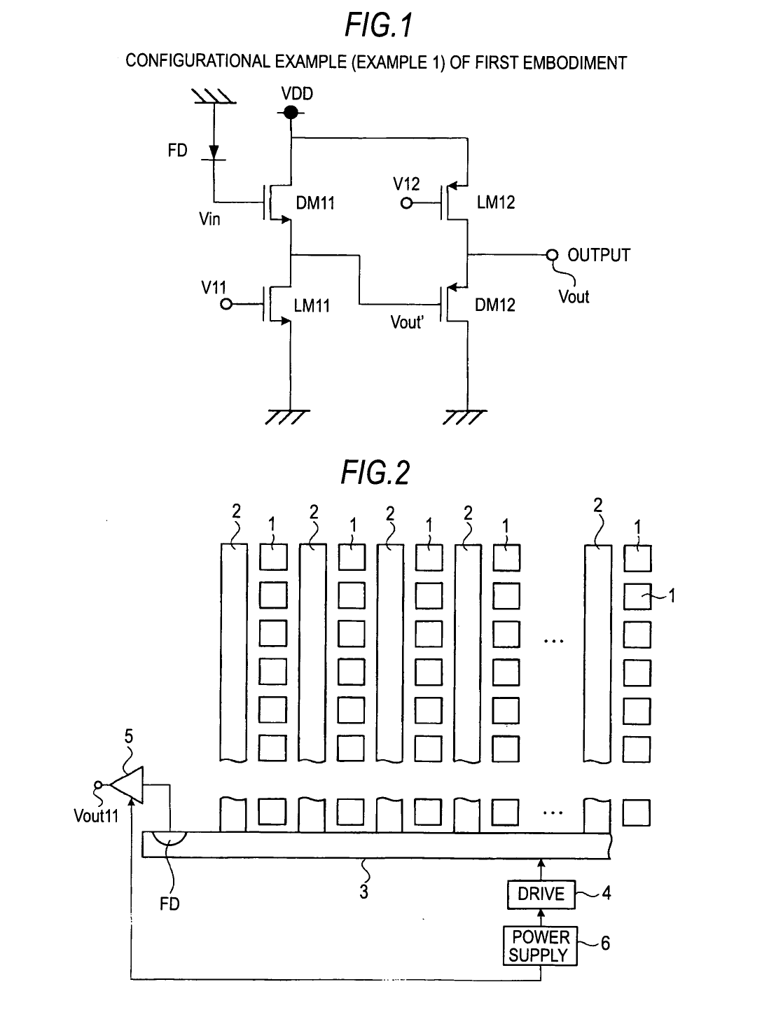

Examples of preferred embodiments of the present invention will be described below with reference to FIGS. 1 to 13. The description will be given in the following order.

1. Configuration of First Embodiment [Example 1: FIGS. 1 to 4A, 4B and 4C]

2. Modification of First Embodiment [Example 2: FIG. 5]

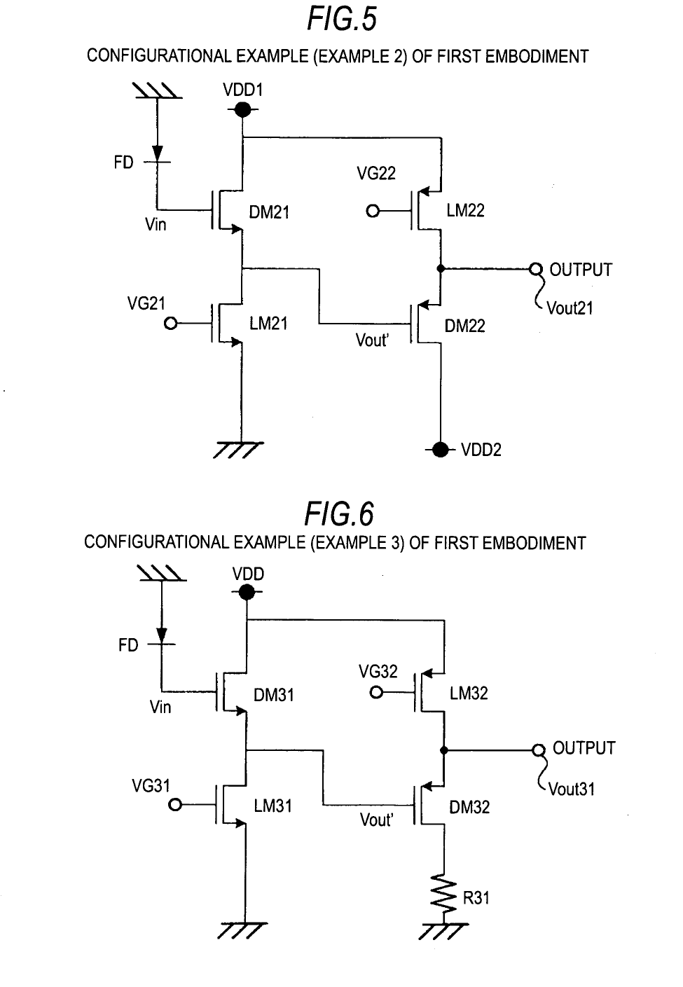

3. Modification of First Embodiment [Example 3: FIG. 6]

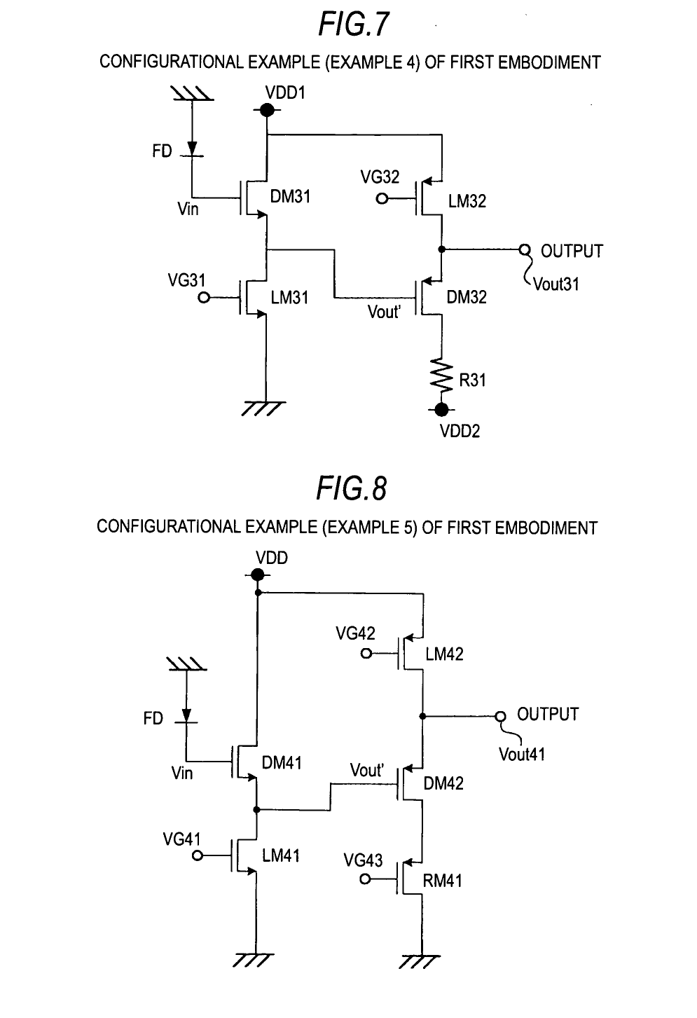

4. Modification of First Embodiment [Example 4: FIG. 7]

5. Modification of First Embodiment [Example 5: FIG. 8]

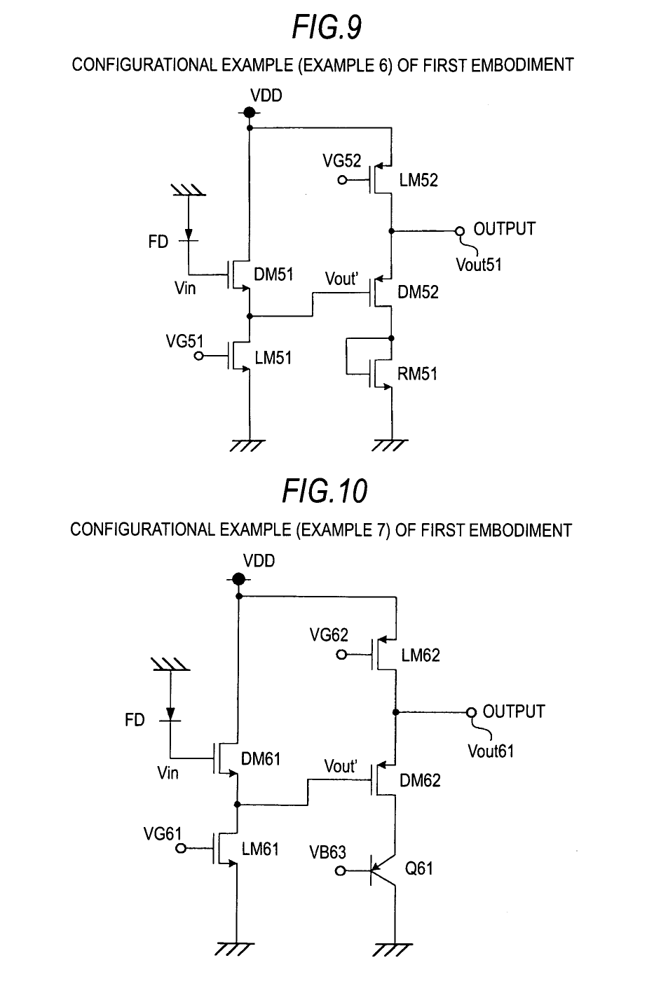

6. Modification of First Embodiment [Example 6: FIG. 9]

7. Modification of First Embodiment [Example 7: FIG. 10]

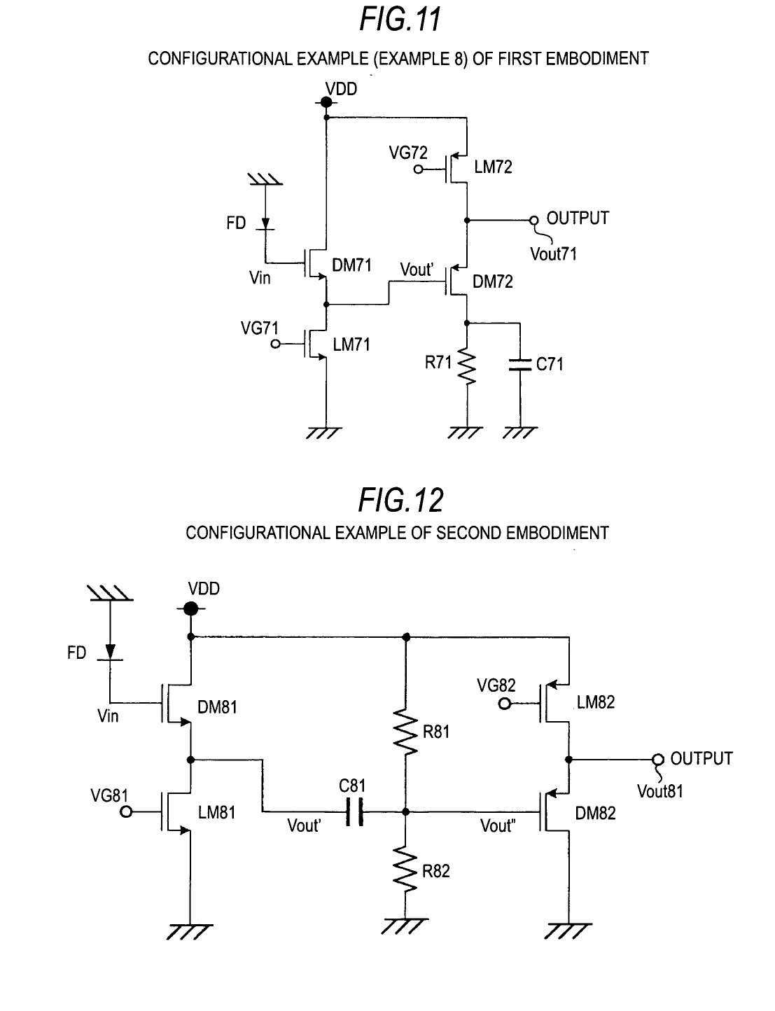

8. Modification of First Embodiment [Example 8: FIG. 11]

9. Configuration of Second Embodiment [FIG. 12]

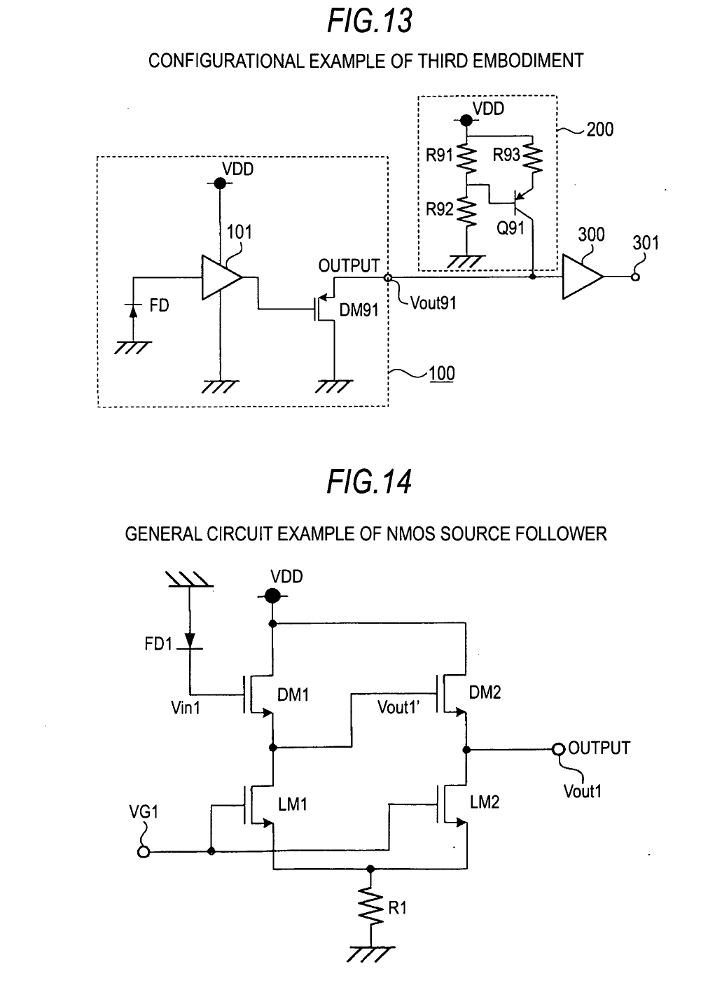

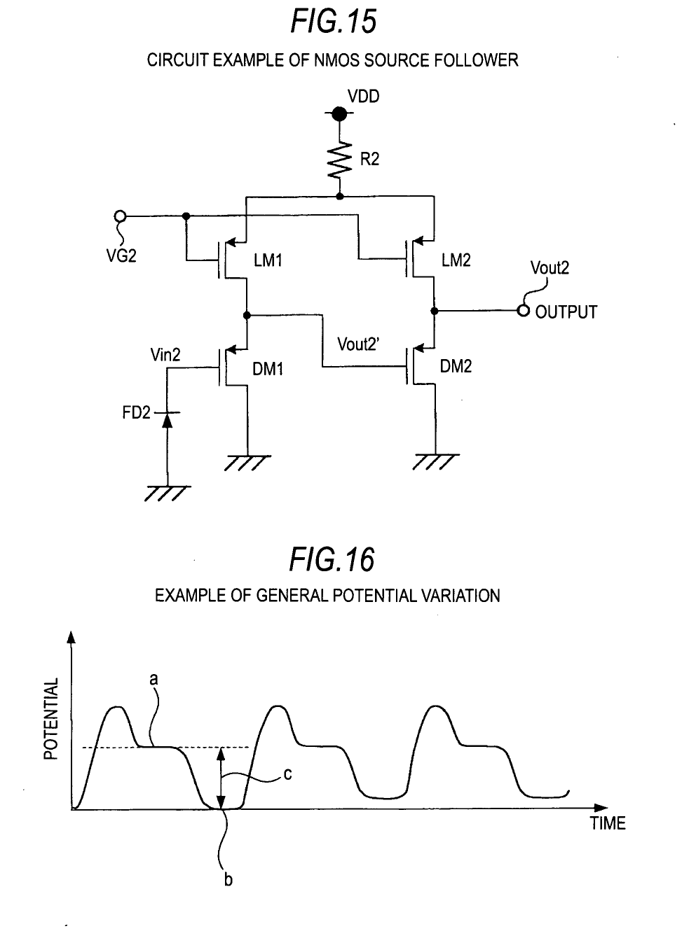

10. Configuration of Third Embodiment [FIG. 13]

### 1. Example of First Embodiment

### [General Configuration of CCD Solid-State Imaging Device]

An example of the first embodiment will be described below.

First, referring to FIG. 2, the general configuration of a CCD solid-state imaging device according to the example of the embodiment will be described.

As shown in FIG. 2, pixels 1 each having a light receiving element like a photodiode are laid out in a matrix form in predetermined quantities vertically and horizontally. Each pixel 1 is connected with a vertical CCD 2 which is a vertical transfer section, so that a signal charge stored in each pixel 1 is read out and transferred vertically. The transfer of the signal charge by the vertical CCD 2 is executed in synchronism with a transfer pulse supplied from a drive circuit 4.

A horizontal CCD 3 is disposed at an end portion of the vertical CCD 2 (lower end in the configuration in FIG. 2) to sequentially and horizontally transfer the signal charges of individual pixels transferred from the vertical CCD 2. The transfer of the signal charge by the horizontal CCD 3 is likewise executed in synchronism with the transfer pulse supplied from the drive circuit 4.

A floating diffusion FD formed by a PN junction diode is provided at an end portion of the horizontal CCD 3. A signal acquired by the floating diffusion FD is supplied to an output circuit 5. According to the embodiment, the output circuit 5 is configured to have a plurality of source follower circuits connected. A signal which is processed by the output circuit 5 is output from an output terminal Vout11 as an imaging signal output of the CCD solid-state imaging device.

The imaging signal output from the output terminal Vout11 is processed to be an image signal of a predetermined format by an imaging signal processing section in an imaging apparatus (camera). The processed image signal is output from the imaging apparatus, and is stored in a storage medium (recording medium) in the imaging apparatus as needed. It is to be noted that an optical part like a lens is mounted in the imaging apparatus, so that image light of a subject acquired by the optical part is focused on the location where the pixels 1 of the CCD solid-state imaging device are arranged, thereby forming an image thereat.

### Configurational Example of Output Circuit (Example 1)

Next, the configuration of the output circuit of the CCD solid-state imaging device according to the embodiment will be described referring to FIG. 1.

The output circuit according to the embodiment is configured to have two (first and last) source follower circuits. In this example, as shown in FIG. 1, the first source follower circuit is configured to have a driver MOS transistor DM11 formed by an N-channel MOS transistor, and a load MOS transistor LM11 formed by an N-channel MOS transistor. The last source follower circuit is configured to have a driver MOS transistor DM12 formed by a P-channel MOS transistor, and a load MOS transistor LM12 formed by a P-channel MOS transistor. The driver MOS transistor DM11, DM12 receives an input signal at its gate and outputs the input signal as a source voltage. The load MOS transistor LM11, LM12 permits a constant current to flow as an offset current.

A voltage signal Vin acquired at the floating diffusion FD is supplied to the gate of the driver MOS transistor DM11 of the first source follower circuit. A supply voltage VDD is supplied to the drain of the driver MOS transistor DM11. The source of the driver MOS transistor DM11 is connected to the drain of the load MOS transistor LM11 whose source is connected to the ground potential portion. A gate input voltage VG11 is supplied to the gate of the load MOS transistor LM11.

A signal Vout′, which is the output of the first source follower circuit acquired at the node between the source of the driver MOS transistor DM11 and the drain of the load MOS transistor LM11, is supplied to the last source follower circuit. That is, the output Vout′ of the first source follower circuit is supplied to the gate of the driver MOS transistor DM12 of the last source follower circuit. The driver MOS transistor DM12 has a drain connected to the ground potential portion, and a source connected to the drain of the load MOS transistor LM12. The supply voltage VDD is supplied to the source of the load MOS transistor LM12. A gate input voltage VG12 is supplied to the gate of the load MOS transistor LM12. The gate input voltages VG11, VG12, which are fixed voltages, is supplied from a power supply circuit 6 (FIG. 2) that supplies the power supply to the drive circuit in the CCD solid-state imaging device. Alternatively, the configuration may be modified too supply the power supply from a power supply circuit separate from the power supply circuit inside the imaging device.

An output signal Vout11 of the solid-state imaging device is acquired at the node between the drain of the load MOS transistor LM12 and the source of the driver MOS transistor DM12.

In case where the load MOS transistor LM11 is designed to be a depletion type NMOS transistor, the gate input voltage VG11 may be the ground potential. In case where the load MOS transistor LM12 is designed to be a depletion type PMOS transistor, the gate input voltage VG12 may be directly connected to the supply voltage VDD.

### Structural Example of P-Channel MOS Transistor

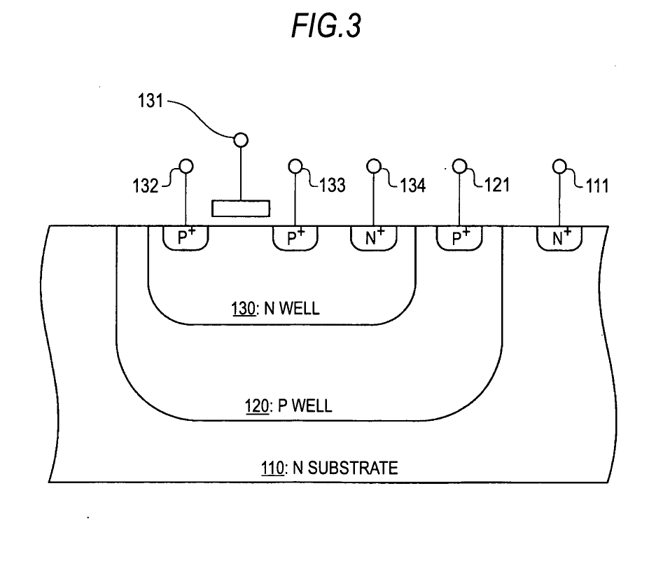

FIG. 3 is a cross-sectional view showing an example of the structure of a P-channel MOS transistor as the driver MOS transistor DM12 of the last source follower circuit.

In this example, an N-type substrate 110 is used as the substrate of the solid-state imaging device. The use of the N-type substrate 110 as the substrate of the solid-state imaging device can permit adjustment of the amount of saturated charges in the pixel section (light receiving section) and signal-charge sweeping of the electric shutter by adjusting the substrate voltage. It is to be noted however that the direct use of the N-type substrate 110 as the back gate of the P-channel MOS transistor of the output circuit is not proper because such usage varies the threshold voltage.

In this example, therefore, a P-well 120 is formed in the N-type substrate 110, and an N-well 130 is formed in the P-well 120, as shown in FIG. 3. Then, the P-channel MOS transistor (driver MOS transistor DM12) is formed in the N-well 130. In the example in FIG. 3, a gate electrode part 131, a drain electrode part 132, a source electrode part 133, and an N-well electrode part 134 are provided to form the P-channel MOS transistor.

This structure can permit the P-channel MOS transistor of the output circuit to be formed adequately.

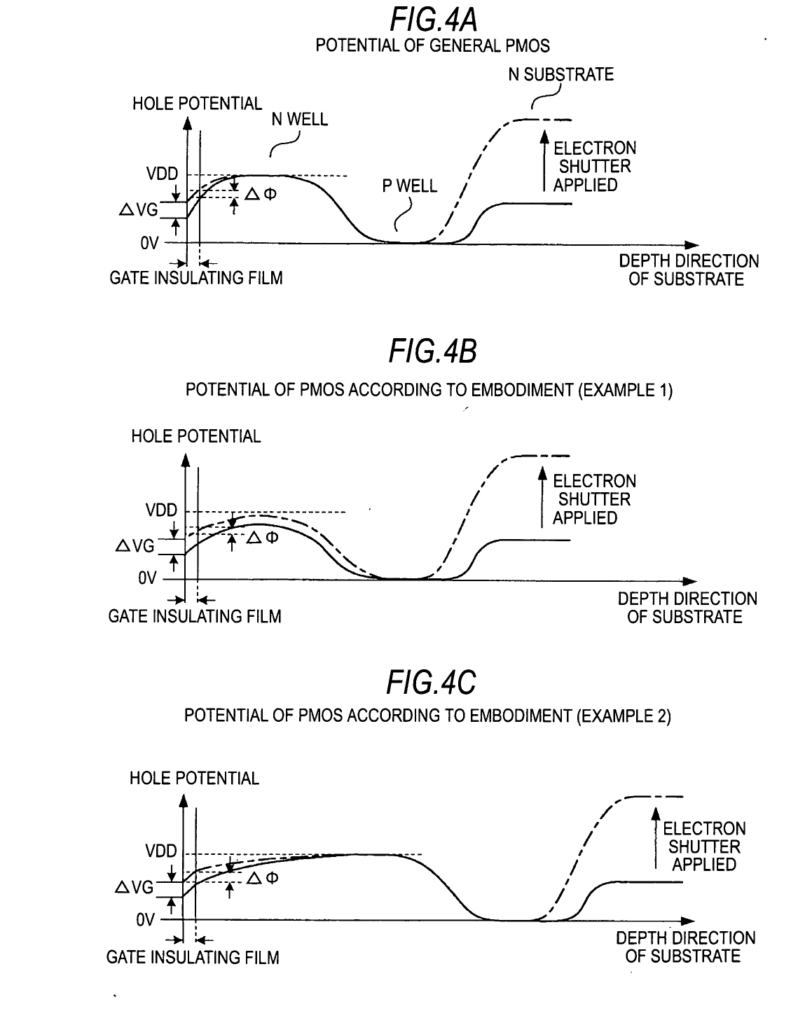

Next, the structure for preventing reduction in the gain of the source follower circuit formed by P-channel MOS transistors will be described referring to FIGS. 4A to 4C.

To prevent reduction in the gain of the source follower circuit formed by P-channel MOS transistors, it is desirable to make the mutual conductance gmb, with respect to the substrate voltage smaller.

FIG. 4A is a potential chart of a general P-channel MOS transistor. The abscissa represents the depth direction in the substrate, and the ordinate represents the potential of holes. The origin of the depth direction in the substrate indicates the lower end of the gate electrode. The solid line in FIG. 4A represents the case where an electronic shutter is not applied, and the long dashed short dashed line represents the case where an electronic shutter is applied. It is apparent that with the P-well being fixed to 0 V, as shown in FIG. 4A, the channel potential is not influenced by the electronic shutter. When the gate bias is changed by ΔVG, the channel changes by Δφ, which is smaller than the change ΔVG of the gate bias. The smaller the difference between ΔVG and Δφ, the smaller the mutual conductance gmb becomes.

FIG. 4B shows an example (example 1) of the potential chart of the P-channel MOS transistor in the source follower circuit according to the embodiment. The solid line in FIG. 4B represents the case where an electronic shutter is not applied, and the long dashed short dashed line represents the case where an electronic shutter is applied.

According to the embodiment, the N-well is made to have a lower concentration to be depleted. This increases the amount of the change Δφ in channel with respect to the change ΔVG in gate bias, making the mutual conductance gmb smaller. The concentration of the N-type impurity of the N-well has a peak in the range of 0.5 μm to 1.5 μm, which can be achieved by setting the concentration to, for example, 0.5×10¹⁶/cm³ to 2.0×10¹⁶/cm³ or so.

FIG. 4C shows another example (example 2) of the potential chart of the P-channel MOS transistor in the source follower circuit according to the embodiment. The solid line in FIG. 4C represents the case where an electronic shutter is not applied, and the long dashed short dashed line represents the case where an electronic shutter is applied.

In this example, the N-well is formed neutral at a deep position in the substrate in the depth direction. It is apparent that this formation of the N-well increases the amount of the change Δφ in channel with respect to the change ΔVG in gate bias, making the mutual conductance gmb smaller.

The concentration of the N-type impurity of the N-well has a peak in the range of 2 μm to 4 μm, and is set to 1.5×10¹⁶/cm³ to 6.0×10¹⁶/cm³ or so. The concentration of the P-type impurity of the P-well has a peak deeper by 1 μm to 3 μm than the peak of the N-type impurity of the N-well, which can be achieved by setting the concentration to 1.5×10¹⁶/cm³ to 6.0×10¹⁶/cm³ or so.

### Effects of First Embodiment

The use of the output circuit according to the embodiment with the foregoing configuration can provide a CCD solid-state imaging device which can use a source follower circuit formed by P-channel MOS transistors while suppressing the hot carriers and reducing the supply voltage. This brings about effects of securing a sufficient fall characteristic with low power consumption, which are advantages of the source follower circuit formed by P-channel MOS transistors, and reducing noise in the output circuit by reducing 1/f noise.

That is, designing the last source follower circuit with P-channel MOS transistors as configured in FIG. 1 can lower the power consumption. Further, the characteristics of the output circuit can be improved by configuring the first source follower circuit with N-channel MOS transistors and using an enhanced driver MOS transistor in the first source follower circuit.

To improve the rise slew rate of the source follower circuit formed by P-channel MOS transistors, the gates of the load MOS transistors LM21, LM22 may be actively driven by a reset gate pulse or the like.

In addition, designing the first source follower circuit with N-channel MOS transistors as configured in FIG. 1 can set the supply voltage lower than that achieved in the case of the first source follower circuit designed with P-channel MOS transistors. Further, the hot carriers in the driver MOS transistor DM12 in the first source follower circuit formed by N-channel MOS transistors can be suppressed by using an enhanced driver MOS transistor DM11 in the first source follower circuit. This is because the first output Vout′ can be set lower than that achieved in the case of designing the first source follower circuit with the enhanced P-channel MOS tansistor.

Further, using a depletion type MOS transistor in the last source follower circuit can reduce the potential difference between the source and drain of the driver MOS transistor DM12, thus improving the characteristics.

Next, configurations of modifications of the output circuit according to the first embodiment will be described one by one referring to FIGS. 5 to 11.

### 2. Modification Example of First Embodiment [Example 2: FIG. 5]

FIG. 5 shows the configuration where a supply voltage VDD2 is applied to the drain of a driver MOS transistor DM22 in the last source follower circuit.

As shown in FIG. 5, the first source follower circuit is configured to have a driver MOS transistor DM21 formed by an N-channel MOS transistor, and a load MOS transistor LM21 formed by an N-channel MOS transistor. The last source follower circuit is configured to have a driver MOS transistor DM22 formed by a P-channel MOS transistor, and a load MOS transistor LM22 formed by a P-channel MOS transistor.

A voltage signal Vin acquired at the floating diffusion FD is supplied to the gate of the driver MOS transistor DM21 of the first source follower circuit. A first supply voltage VDD1 is supplied to the drain of the driver MOS transistor DM21. The source of the driver MOS transistor DM21 is connected to the drain of the load MOS transistor LM21 whose source is connected to the ground potential portion. A gate input voltage VG21 is supplied to the gate of the load MOS transistor LM21.

The signal which is the output of the first source follower circuit acquired at the node between the source of the driver MOS transistor DM21 and the drain of the load MOS transistor LM21 is supplied to the last source follower circuit. That is, the output of the first source follower circuit is supplied to the gate of the driver MOS transistor DM22 of the last source follower circuit. The second supply voltage VDD2 is supplied to the drain of the driver MOS transistor DM22.

The second supply voltage VDD2 is a different voltage from the first supply voltage VDD1, and is, for example, 2 V to 6 V or so.

The source of the driver MOS transistor DM22 is connected to the drain of the load MOS transistor LM22. The first supply voltage VDD1 is supplied to the source of the load MOS transistor LM22. A gate input voltage VG22 is supplied to the gate of the load MOS transistor LM22.

An output imaging signal Vout21 of the solid-state imaging device is acquired at the node between the drain of the load MOS transistor LM22 and the source of the driver MOS transistor DM22.

The configuration shown in FIG. 5 can prevent generation of hot carriers as compared with the case where the drain voltage of the driver MOS transistor DM22 in the last source follower circuit is the ground potential as shown in FIG. 1.

The second supply voltage VDD2, if commonly used to drive, for example, the horizontal CCD 3 (FIG. 2), can prevent the number of power source systems in the power source circuit from increasing.

### 3. Modification Example of First Embodiment [Example 3: FIG. 6]

FIG. 6 shows the configuration where a resistor is connected to the drain of a driver MOS transistor DM32 in the last source follower circuit.

As shown in FIG. 6, the first source follower circuit is configured to have a driver MOS transistor DM31 formed by an N-channel MOS transistor, and a load MOS transistor LM31 formed by an N-channel MOS transistor. The last source follower circuit is configured to have a driver MOS transistor DM32 formed by a P-channel MOS transistor, and a load MOS transistor LM32 formed by a P-channel MOS transistor.

The voltage signal Vin acquired at the floating diffusion FD is supplied to the gate of the driver MOS transistor DM31 of the first source follower circuit. The supply voltage VDD is supplied to the drain of the driver MOS transistor DM31. The source of the driver MOS transistor DM31 is connected to the drain of the load MOS transistor LM31 whose source is connected to the ground potential portion. A gate input voltage VG31 is supplied to the gate of the load MOS transistor LM31.

The signal which is the output of the first source follower circuit acquired at the node between the source of the driver MOS transistor DM31 and the drain of the load MOS transistor LM31 is supplied to the last source follower circuit. That is, the output of the first source follower circuit is supplied to the gate of the driver MOS transistor DM32 of the last source follower circuit: The drain of the driver MOS transistor DM32 is connected via a resistor R31 to the ground potential portion.

The source of the driver MOS transistor DM32 is connected to the drain of the load MOS transistor LM32. The supply voltage VDD is supplied to the source of the load MOS transistor LM32. A gate input voltage VG32 is supplied to the gate of the load MOS transistor LM32.

An output imaging signal Vout31 of the solid-state imaging device is acquired at the node between the drain of the load MOS transistor LM32 and the source of the driver MOS transistor DM32.

The connection of the resistor R31 to the drain of the driver MOS transistor DM32 as shown in FIG. 6 can permit the drain voltage of the driver MOS transistor DM32 to be properly set to prevent generation of hot carriers as in the case of FIG. 5.

### 4. Modification Example of First Embodiment [Example 4: FIG. 7]

FIG. 7 shows the configuration where another supply voltage VDD2 is connected via a resistor R32 to the drain of the driver MOS transistor DM32 in the last source follower circuit.

As shown in FIG. 7, the first supply voltage VDD1 is supplied to the drain of the driver MOS transistor DM31 and the source of the load MOS transistor LM32. The second supply voltage VDD2 is supplied via the resistor R32 to the drain of the driver MOS transistor DM32 in the last source follower circuit. The other portions are the same as those in the configuration of FIG. 6.

The configuration shown in FIG. 7 can also permit the drain voltage of the driver MOS transistor DM32 to be properly set to prevent generation of hot carriers. The example in FIG. 7 may likewise be configured so that the second supply voltage VDD2 may be commonly used to drive, for example, the horizontal CCD 3 (FIG. 2), thereby preventing the number of power source systems in the power source circuit from increasing.

### 5. Modification Example of First Embodiment [Example 5: FIG. 8]

FIG. 8 shows the configuration where a nonlinear resistor formed by a P-channel MOS transistor RM41 is connected to the drain of a driver MOS transistor DM42 in the last source follower circuit.

As shown in FIG. 8, the first source follower circuit is configured to have a driver MOS transistor DM41 formed by an N-channel MOS transistor, and a load MOS transistor LM41 formed by an N-channel MOS transistor. The last source follower circuit is configured to have a driver MOS transistor DM42 formed by a P-channel MOS transistor, and a load MOS transistor LM42 formed by a P-channel MOS transistor.

The voltage signal Vin acquired at the floating diffusion FD is supplied to the gate of the driver MOS transistor DM41 of the first source follower circuit. The supply voltage VDD is supplied to the drain of the driver MOS transistor DM41. The source of the driver MOS transistor DM41 is connected to the drain of the load MOS transistor LM41 whose source is connected to the ground potential portion. A gate input voltage VG41 is supplied to the gate of the load MOS transistor LM41.

The signal which is the output of the first source follower circuit acquired at the node between the source of the driver MOS transistor DM41 and the drain of the load MOS transistor LM41 is supplied to the last source follower circuit. That is, the output of the first source follower circuit is supplied to the gate of the driver MOS transistor DM42 of the last source follower circuit. The drain of the driver MOS transistor DM42 is connected with the source of the P-channel MOS transistor RM41 functioning as a linear resistor, whose drain is grounded. The gate of the MOS transistor RM41 is supplied with a gate input voltage VG43 which is a fixed voltage.

The source of the driver MOS transistor DM42 is connected to the drain of the load MOS transistor LM42. The supply voltage VDD is supplied to the source of the load MOS transistor LM42. A gate input voltage VG42 is supplied to the gate of the load MOS transistor LM42.

An output imaging signal Vout41 of the solid-state imaging device is acquired at the node between the drain of the load MOS transistor LM42 and the source of the driver MOS transistor DM42.

The connection of the P-channel MOS transistor RM41, which functions as a nonlinear resistor, to the drain of the driver MOS transistor DM42 as shown in FIG. 8 can permit the drain voltage of the driver MOS transistor DM42 to be properly set to prevent generation of hot carriers. In the case of the example in FIG. 8, the drain voltage of the driver MOS transistor DM42 can be increased by more than necessary with a low impedance (e.g., several tens of Ω or less).

### 6. Modification Example of First Embodiment [Example 6: FIG. 9]

FIG. 9 shows the configuration where a nonlinear resistor formed by a diode-connected N-channel MOS transistor RM51 is connected to the drain of a driver MOS transistor DM52 in the last source follower circuit.

As shown in FIG. 9, the first source follower circuit is configured to have a driver MOS transistor DM51 formed by an N-channel MOS transistor, and a load MOS transistor LM51 formed by an N-channel MOS transistor. The last source follower circuit is configured to have a driver MOS transistor DM52 formed by a P-channel MOS transistor, and a load MOS transistor LM52 formed by a P-channel MOS transistor.

The voltage signal Vin acquired at the floating diffusion FD is supplied to the gate of the driver MOS transistor DM51 of the first source follower circuit. The supply voltage VDD is supplied to the drain of the driver MOS transistor DM51. The source of the driver MOS transistor DM51 is connected to the drain of the load MOS transistor LM51 whose source is connected to the ground potential portion. A gate input voltage VG51 is supplied to the gate of the load MOS transistor LM51.

The signal which is the output of the first source follower circuit acquired at the node between the source of the driver MOS transistor DM51 and the drain of the load MOS transistor LM51 is supplied to the last source follower circuit. That is, the output of the first source follower circuit is supplied to the gate of the driver MOS transistor DM52 of the last source follower circuit. The drain of the driver MOS transistor DM52 is connected with the drain and gate of the N-channel MOS transistor RM51. The N-channel MOS transistor RM51 is configured to have the drain and gate connected together to serve as a diode, and have the source grounded.

The source of the driver MOS transistor DM52 is connected to the drain of the load MOS transistor LM52. The supply voltage VDD is supplied to the source of the load MOS transistor LM52. A gate input voltage VG52 is supplied to the gate of the load MOS transistor LM52.

An output imaging signal Vout51 of the solid-state imaging device is acquired at the node between the drain of the load MOS transistor LM52 and the source of the driver MOS transistor DM52.

The connection of the diode-connected MOS transistor RM51, which functions as a nonlinear resistor, to the drain of the driver MOS transistor DM52 as shown in FIG. 9 can permit the drain voltage of the driver MOS transistor DM52 to be properly set to prevent generation of hot carriers.

### 7. Modification Example of First Embodiment [Example 7: FIG. 10]

FIG. 10 shows the configuration where a nonlinear resistor formed by a PNP type bipolar transistor Q61 is connected to the drain of a driver MOS transistor DM62 in the last source follower circuit.

As shown in FIG. 10, the first source follower circuit is configured to have a driver MOS transistor DM61 formed by an N-channel MOS transistor, and a load MOS transistor LM61 formed by an N-channel MOS transistor. The last source follower circuit is configured to have a driver MOS transistor DM62 formed by a P-channel MOS transistor, and a load MOS transistor LM62 formed by a P-channel MOS transistor.

The voltage signal Vin acquired at the floating diffusion FD is supplied to the gate of the driver MOS transistor DM61 of the first source follower circuit. The supply voltage VDD is supplied to the drain of the driver MOS transistor DM61. The source of the driver MOS transistor DM61 is connected to the drain of the load MOS transistor LM61 whose source is connected to the ground potential portion. Agate input voltage VG61 is supplied to the gate of the load MOS transistor LM61.

The signal which is the output of the first source follower circuit acquired at the node between the source of the driver MOS transistor DM61 and the drain of the load MOS transistor LM61 is supplied to the last source follower circuit. That is, the output of the first source follower circuit is supplied to the gate of the driver MOS transistor DM62 of the last source follower circuit. The drain of the driver MOS transistor DM62 is connected with the emitter of the PNP type bipolar transistor Q61. This transistor Q61 has a collector grounded, and a base supplied with a base voltage VB63, which is a fixed voltage. The transistor Q61 is connected as a nonlinear resistor.

The source of the driver MOS transistor DM62 is connected to the drain of the load MOS transistor LM62. The supply voltage VDD is supplied to the source of the load MOS transistor LM62. A gate input voltage VG62 is supplied to the gate of the load MOS transistor LM62.

An output imaging signal Vout61 of the solid-state imaging device is acquired at the node between the drain of the load MOS transistor LM62 and the source of the driver MOS transistor DM62.

The connection of the PNP type bipolar transistor Q61, which functions as a nonlinear resistor, to the drain of the driver MOS transistor DM62 as shown in FIG. 10 can permit the drain voltage of the driver MOS transistor DM62 to be properly set to prevent generation of hot carriers.

### 8. Modification Example of First Embodiment [Example 8: FIG. 11]

FIG. 11 shows the configuration where a parallel circuit of resistor R71 and a capacitor C71 is connected to the drain of a driver MOS transistor DM72 in the last source follower circuit.

As shown in FIG. 11, the first source follower circuit is configured to have a driver MOS transistor DM71 formed by an N-channel MOS transistor, and a load MOS transistor LM71 formed by an N-channel MOS transistor. The last source follower circuit is configured to have a driver MOS transistor DM72 formed by a P-channel MOS transistor, and a load MOS transistor LM72 formed by a P-channel MOS transistor.

The voltage signal Vin acquired at the floating diffusion FD is supplied to the gate of the driver MOS transistor DM71 of the first source follower circuit. The supply voltage VDD is supplied to the drain of the driver MOS transistor DM71. The source of the driver MOS transistor DM71 is connected to the drain of the load MOS transistor LM71 whose source is connected to the ground potential portion. A gate input voltage VG71 is supplied to the gate of the load MOS transistor LM71.

The signal which is the output of the first source follower circuit acquired at the node between the source of the driver MOS transistor DM71 and the drain of the load MOS transistor LM71 is supplied to the last source follower circuit. That is, the output of the first source follower circuit is supplied to the gate of the driver MOS transistor DM72 of the last source follower circuit. The drain of the driver MOS transistor DM72 is connected with one ends of the resistor R71 and capacitor C71 whose other ends are grounded.

The source of the driver MOS transistor DM72 is connected to the drain of the load MOS transistor LM72. The supply voltage VDD is supplied to the source of the load MOS transistor LM72. A gate input voltage VG72 is supplied to the gate of the load MOS transistor LM72.

An output imaging signal Vout71 of the solid-state imaging device is acquired at the node between the drain of the load MOS transistor LM72 and the source of the driver MOS transistor DM72.

The drain voltage of the driver MOS transistor DM72 can also be set properly by connecting the parallel circuit of the resistor R71 and the capacitor C71 to the drain of the driver MOS transistor DM72 as shown in FIG. 11. In the configuration of FIG. 11, the drain-side resistor of the driver MOS transistor DM72 is made to have an AC characteristic. Although a linear resistor with a sufficiently high resistance may be used as the resistor R71, any of the nonlinear resistors in the other examples described above may be used as well. The capacitor C71 may be grounded within the chip on which the CCD solid-state imaging device is configured, or grounded outside the chip. Further, the ground potential may be a predetermined power supply connected besides 0 V or the so-called ground portion.

Although the first source follower circuit in the output circuit is formed by N-channel MOS transistors in each of the above-described examples of the first embodiment, the first source follower circuit may be formed by P-channel MOS transistors. It is to be noted however that while designing the last source follower circuit with P-channel MOS transistors provides the greatest effect of reducing power consumption, designing the first source follower circuit with P-channel MOS transistors does not lower the power consumption so much. Because the ratio of 1/f noise in the first source follower circuit in the circuit noise is large, however, designing the first source follower circuit with P-channel MOS provides a significant effect from the viewpoint of noise reduction. In this case, the use of a depletion type MOS transistor for the driver MOS transistor can suppress the supply voltage low, suppressing the hot carriers.

If all of the source follower circuits are formed by P-channel MOS transistors, it is desirable to use a depletion type driver MOS transistor at least in the first source follower circuit formed by P-channel MOS transistors. This configuration can suppress the supply voltage, thereby suppressing the hot carriers.

### 9. Configuration of Second Embodiment [FIG. 12]

The second embodiment of the invention will be described referring to FIG. 12. The general configuration of a CCD solid-state imaging device according to the second embodiment is the same as the configuration of the first embodiment which has already been described referring to the drawings including FIG. 1. The output circuit of the CCD solid-state imaging device according to the second embodiment has the configuration shown in FIG. 12.

Referring to FIG. 12, the output circuit is configured to have two (first and last) source follower circuits with a DC cutting capacitor connected between the first source follower circuit and the last source follower circuit. Further, a resistor-divided DC voltage is supplied to the last source follower circuit.

As shown in FIG. 12, the first source follower circuit is configured to have a driver MOS transistor DM81 formed by an N-channel MOS transistor, and a load MOS transistor LM81 formed by an N-channel MOS transistor. The last source follower circuit is configured to have a driver MOS transistor DM82 formed by a P-channel MOS transistor, and a load MOS transistor LM82 formed by a P-channel MOS transistor.

The voltage signal Vin acquired at the floating diffusion FD is supplied to the gate of the driver MOS transistor DM81 of the first source follower circuit. The supply voltage VDD is supplied to the drain of the driver MOS transistor DM81. The source of the driver MOS transistor DM81 is connected to the drain of the load MOS transistor LM81 whose source is connected to the ground potential portion. A gate input voltage VG81 is supplied to the gate of the load MOS transistor LM81.

The signal which is the output of the first source follower circuit acquired at the node between the source of the driver MOS transistor DM81 and the drain of the load MOS transistor LM81 is supplied to the last source follower circuit via a capacitor C81. That is, the output Vout′ of the first source follower circuit is supplied to the gate of the driver MOS transistor DM82 of the last source follower circuit via the capacitor C81. The node between a resistor R81 and a resistor R82 is connected between the capacitor C81 and the gate of the driver MOS transistor DM82. The resistors R81, R82 is connected between the supply voltage VDD and the ground potential portion as shown in FIG. 12, so that the supply voltage divided by the resistors R81, R82 is applied to the gate of the driver MOS transistor DM82. As a result, an output Vout″ which is supplied to the last source follower circuit is the voltage signal set by the resistors R81, R82.

The drain of the driver MOS transistor DM82 is grounded in this example. The source of the driver MOS transistor DM82 is connected to the drain of the load MOS transistor LM82. The supply voltage VDD is supplied to the source of the load MOS transistor LM82. A gate input voltage VG82 is supplied to the gate of the load MOS transistor LM82.

An output imaging signal Vout81 of the solid-state imaging device is acquired at the node between the drain of the load MOS transistor LM82 and the source of the driver MOS transistor DM82.

The configuration shown in FIG. 12 can permit the DC voltage to be adjusted independently by the first source follower circuit formed by N-channel MOS transistors and the last source follower circuit formed by P-channel MOS transistors. It is therefore possible to easily adjust the DC voltage in such a way as to select an operational point at which hot carriers are not generated.

Although the configuration in FIG. 12 has two source follower circuits, one formed by N-channel MOS transistors and the other formed by P-channel MOS transistors, the output circuit may be configured to have three or more source follower circuits in which case the resistor-divided voltage may likewise be applied via the DC cutting capacitor. In case where the output circuit is configured to have three source follower circuits, for example, the first and second source follower circuits are formed by N-channel MOS transistors, and the third (last) source follower circuit is formed by P-channel MOS transistors. Alternatively, the first source follower circuit is formed by N-channel MOS transistors, and the second and third (last) source follower circuits are formed by P-channel MOS transistors. The output circuit may be configured to have four or more source follower circuits.

Although the drain of the driver MOS transistor DM82 is grounded in the configuration in FIG. 12, an element such as a linear resistor or a nonlinear resistor may be connected thereto as described in the foregoing descriptions of the individual modification examples of the first embodiment.

Further, the configuration explained referring to FIGS. 4A to 4C to prevent reduction in the gain of the source follower circuit formed by P-channel MOS transistors may be adapted to the configuration in FIG. 12.

### 10. Configuration of Third Embodiment [FIG. 13]

The third embodiment of the invention will be described referring to FIG. 13. In the third embodiment, the output circuit of the CCD solid-state imaging device is configured to be of an open source type.

As shown in FIG. 13, an imager section 100 constituting the CCD solid-state imaging device is configured to connect a floating diffusion FD to a source follower circuit 101 and supply the output of the source follower circuit 101 to a P-channel MOS transistor 91. An output Vout91 is acquired from the source of the P-channel MOS transistor 91. The drain of the P-channel MOS transistor 91 is grounded. The source follower circuit 101 may be formed by either N-channel MOS transistors or P-channel MOS transistors.

In case where the output Vout91 of the CCD solid-state imaging device is supplied to an output terminal 301 via a buffer amplifier 300 in the example in FIG. 13, a current flow circuit 200 is connected to the input of the buffer amplifier 300.

The current flow circuit 200 provided outside the imager section 100 is configured to supply a voltage acquired by, for example, dividing the supply voltage VDD by resistors R91 and R92 to the base of a transistor Q91. With the supply voltage VDD supplied to the emitter of the transistor Q91 via a resistor R93, a signal acquired at the collector of the transistor Q91 is supplied to the input of the buffer amplifier 300.

With the current flow circuit 200 provided outside the CCD solid-state imaging device as in the foregoing configuration, the last source follower circuit in the output circuit of the imager section 100 can be designed as an open source type. The configuration in FIG. 13 can reduce power consumption in the imager section 100 which is the CCD solid-state imaging device. The reduction in power consumption brings about an effect of suppressing a temperature rise in the CCD solid-state imaging device.

The circuit configuration of the current flow circuit 200 shown in FIG. 13 is just illustrative, and not restrictive. For example, the current flow circuit may be configured to have a constant current characteristic, thereby providing an improved characteristic.

The present application contains subject matter related to that disclosed in Japanese Priority Patent Application JP 2009-167203 filed in the Japan Patent Office on Jul. 15, 2009, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An output circuit for a CCD solid-state imaging device, comprising:
a first source follower circuit that is supplied with an imaging signal acquired by a floating diffusion, and includes a driver MOS transistor and a load MOS transistor; and
a last source follower circuit that is supplied with an imaging signal amplified by the first source follower circuit, and includes a driver MOS transistor and a load MOS transistor each being a P-channel MOS transistor to provide an output signal.

2. The output circuit according to claim 1, wherein each of the driver MOS transistor and the load MOS transistor of the first source follower circuit is an N-channel MOS transistor.

3. The output circuit according to claim 2, wherein the driver MOS transistor of the first source follower circuit is an enhanced P-channel MOS transistor.

4. The output circuit according to claim 2, wherein the driver MOS transistor of the last source follower circuit is a depletion type P-channel MOS transistor.

5. The output circuit according to claim 1, wherein each of the driver MOS transistor and the load MOS transistor of the first source follower circuit is a P-channel MOS transistor, and the driver MOS transistor of the last source follower circuit is a depletion type P-channel MOS transistor.

6. The output circuit according to claim 1, wherein a power supply separate from a circuit power supply is connected to a drain terminal of the driver MOS transistor of the last source follower circuit including the P-channel MOS transistors.

7. The output circuit according to claim 6, wherein a power supply supplying power to a drive circuit for a horizontal transfer register is used as the separate power supply.

8. The output circuit according to claim 6, wherein the drain terminal of the driver MOS transistor of the last source follower circuit including the P-channel MOS transistors is connected to the separate power supply via a resistive element.

9. The output circuit according to claim 1, wherein the drain terminal of the driver MOS transistor of the last source follower circuit including the P-channel MOS transistors is grounded via a resistive element.

10. The output circuit according to claim 9, wherein the resistive element is a resistor formed by a gate-grounded P-channel MOS transistor.

11. The output circuit according to claim 9, wherein the resistive element is a resistor formed by a diode-connected N-channel MOS transistor.

12. The output circuit according to claim 9, wherein the resistive element is a resistor formed by a base-grounded PNP bipolar transistor.

13. The output circuit according to claim 9, wherein the resistive element is connected with a capacitor element in parallel.

14. The output circuit according to claim 2, further comprising a plurality of source follower circuits including an output of the first source follower circuit and the last source follower circuit,
wherein a capacitive element is connected between an output of the first source follower circuit including the N-channel MOS transistors and an input of the last source follower circuit including the P-channel MOS transistors, and a DC bias is connected to the input of the last source follower circuit including the P-channel MOS transistors.

15. The output circuit according to claim 1, wherein an N well of the driver MOS transistor which is the P-channel MOS transistor has a low concentration to be depleted.

16. The output circuit according to claim 1, wherein an N well of the driver MOS transistor which is the P-channel MOS transistor is formed neutral, deep in a substrate direction.

17. The output circuit according to claim 1, wherein the last source follower circuit including the P-channel MOS transistors has an open source so that current control is performed externally.

18. A CCD solid-state imaging device comprising:
a pixel section having a plurality of pixels arranged in a matrix form;
a transfer register that transfer signal charges stored in the pixel section;
a floating diffusion that acquires the signal charges transferred by the transfer register;
a first source follower circuit that is supplied with a signal acquired by the floating diffusion, and includes a driver MOS transistor and a load MOS transistor; and
a last source follower circuit that is supplied with a signal amplified by the first source follower circuit, and includes a driver MOS transistor and a load MOS transistor each being a P-channel MOS transistor to provide an output signal.

19. An imaging apparatus comprising:
a pixel section having a plurality of pixels arranged in a matrix form;
a transfer register that transfer signal charges stored in the pixel section;
a floating diffusion that acquires the signal charges transferred by the transfer register;
a first source follower circuit that is supplied with a signal acquired by the floating diffusion, and includes a driver MOS transistor and a load MOS transistor;
a last source follower circuit that is supplied with a signal amplified by the first source follower circuit, and includes a driver MOS transistor and a load MOS transistor each being a P-channel MOS transistor to provide an output signal; and
an imaging signal processing section that processes the output signal of the last source follower circuit.
